(19) United States
(12) Patent Application Publication
(10) Pub. No.: US 2026/0156855 A1
(43) Pub. Date: Jun. 4, 2026

(54) ISOLATION SCHEMES FOR GROUP III-N DEVICES

(71) Applicant: TEXAS INSTRUMENTS INCORPORATED, Dallas, TX (US)

(72) Inventor: Dong Seup Lee, Allen, TX (US)

(21) Appl. No.: 18/963,898

(22) Filed: Nov. 29, 2024

(51) Int. Cl. H10D 30/47; H01L 21/02; H01L 21/3115; H10D 30/01; H10D 62/85

(52) U.S. Cl. CPC H10D 30/471; H10D 30/015; H10D 62/8503; H10P 14/6334; H10P 30/40

(57) ABSTRACT

Isolation schemes for Group III-N devices are described. In one arrangement, a semiconductor device comprises a semiconductor substrate including an isolation region laterally surrounding a device area, the device area including a gate region, a source region, and a drain region. The semiconductor device further comprises a III-N heterojunction structure over the semiconductor substrate, the III-N heterojunction structure including a buffer layer over the semiconductor substrate and a barrier layer over the buffer layer. The semiconductor device further comprises a p-doped III-N gate over the barrier layer in the gate region, and a passivation layer over the barrier layer and the p-doped III-N gate. The passivation layer extends across the device area and the isolation region, where the passivation layer is exclusive of isolation implant species.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a method of fabricating a semiconductor device is disclosed, where the method comprises, among others, forming a buffer layer over a semiconductor substrate; and forming a barrier layer over the buffer layer, the barrier layer avoiding contact with an isolation implant photoresist during an isolation implantation stage, where the isolation implant photoresist is patterned to expose an isolation region of the semiconductor substrate. The isolation region laterally surrounds a device area of the semiconductor substrate, the device area including a gate region, a source region, and a drain region. The method further includes forming a source electrode in the source region, a drain electrode in the drain region and a gate electrode over a p-GaN gate formed in the gate region.

In one example, a method of fabricating a semiconductor device is disclosed. The method comprises, among others, forming a III-N heterojunction structure over a semiconductor substrate, the III-N heterojunction structure including a buffer layer over the semiconductor substrate and a barrier layer over the buffer layer; and forming a p-GaN layer over the III-N heterojunction structure. The method further includes forming a dielectric cap over the p-GaN layer, the dielectric cap covering the p-GaN layer in a gate region of the semiconductor substrate; and forming a patterned photoresist layer over the dielectric cap and the p-GaN layer, the patterned photoresist layer patterned to expose an isolation region of the semiconductor substrate, where the isolation region laterally surrounds a device area of the semiconductor substrate. The device area includes the gate region, a source region, and a drain region. The method further includes implanting isolation implant species in the isolation region to form the isolation region relative to the area; removing the patterned photoresist layer; removing the p-GaN layer outside the dielectric cap to form a p-GaN gate over the barrier layer in the gate region; removing the dielectric cap; and forming a source electrode in the source region, a drain electrode in the drain region and a gate electrode over the p-GaN gate. In an example arrangement, the dielectric cap may be used as a hard mask to etch the p-GaN material outside the dielectric cap in a removal process.

In one example, a semiconductor device is disclosed where the semiconductor device comprises: a semiconductor substrate including an isolation region laterally surrounding a device area, the device area including a gate region, a source region, and a drain region; and a III-N heterojunction structure over the semiconductor substrate, the III-N heterojunction structure including a buffer layer over the semiconductor substrate and a barrier layer over the buffer layer. The semiconductor device further includes a p-doped III-N gate over the barrier layer in the gate region; and a passivation layer over the barrier layer and the p-doped III-N gate, the passivation layer extending across the device area and the isolation region, where the passivation layer is exclusive of isolation implant species.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A-1H depict cross-sectional views of a semiconductor device including a GaN device at various stages of a process flow including device isolation according to an example of the present disclosure; and

FIGS. 2A and 2B are flowcharts of methods of fabricating a semiconductor device according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials, also referred to as III-N materials, such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride (GaN), to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a gallium nitride (p-GaN) layer including p-type dopants, such as magnesium (Mg) or other suitable p-type dopants. When the p-type dopants are activated, the p-GaN layer may deplete the 2DEG beneath the gate stack at zero or negative gate bias. Applying a positive gate voltage enhances the 2DEG under the gate and turns the EMODE GaN device on to allow current flow between the source and drain.

In some examples, a GaN device may be formed with one or more GaN layers over a suitable semiconductor substrate, e.g., including a silicon substrate. The one or more GaN layers may form a heterojunction structure over the semiconductor substrate, with a p-GaN layer overlying the heterojunction structure for effectuating EMODE device functionality. The p-GaN layer may include appropriate levels of p-type dopants to control the threshold voltage (V_{T} or V_{TH}) of the GaN device. In general, higher threshold voltages are desired in order to reduce the likelihood of accidentally turning on an EMODE device, increase operational margins, reduce leakage current (e.g., off-state I_{DS}), etc.

In some examples, a GaN process flow may include an implantation stage to achieve field isolation of the devices where suitable implant species may be implanted in a defined area of the substrate, e.g., an exposed area of the substrate. Such an area may laterally surround an area where one or more GaN devices may be formed (e.g., device areas or active areas). The implanted species cause damage to the crystallinity of the heterojunction structure in the defined area, thus disrupting or disabling the formation of a 2DEG in the defined area. Consequently, the defined area is rendered inactive for forming GaN devices, resulting in an isolation region operating to electrically isolate areas where GaN devices are located (e.g., areas where the crystallinity of the heterojunction structure is preserved).

In some process flows, a photoresist (PR) may be patterned over a patterned p-GaN layer for facilitating isolation implantation in defined areas of a semiconductor substrate during the formation of a GaN device. In an example implementation, a photoresist may be patterned to expose an isolation region in the semiconductor substrate, where the isolation region may laterally surround a device area of the semiconductor substrate. The device area, which may also be referred to as an active area, contains the patterned p-GaN layer in a gate region of the device area. In such arrangements, the photoresist may directly contact a barrier layer of the heterojunction structure, e.g., an AlGaN layer exposed after patterning the p-GaN layer. Accordingly, there exists a risk that components of the photoresist, e.g., organic compounds comprising carbon-based materials, may contaminate the barrier layer's surface contacting the photoresist. In some arrangements, such organic compounds, also referred to herein as organic contaminants, may cause electron trapping in the barrier layer under certain operating conditions such as in high voltage applications. In this manner, the organic contaminants in a barrier layer may lead to degraded performance in GaN devices.

To avoid barrier layer contamination, some arrangements may include a dielectric layer, e.g., a silicon nitride (SiN) layer, formed over the patterned p-GaN layer and extending across the barrier layer before forming the patterned photoresist. The dielectric layer is therefore operable as a blocking layer for preventing direct contact between the photoresist and the barrier layer. Whereas the barrier layer may be protected against photoresist contaminants, the dielectric layer extending past an active area boundary may be damaged due to exposure to isolation implantation. The damaged dielectric layer can detrimentally impact device reliability, especially where the dielectric layer is also used as a passivation layer in some examples. Although the damaged dielectric layer may be removed and a pristine dielectric layer may be redeposited, such a flow would introduce additional complexity. Further, the barrier layer is exposed to additional thermal cycles required in the redeposition stage, which may negatively impact the performance of a device. Moreover, a higher energy isolation implant may be needed in some implementations because of the blocking dielectric layer disposed over the exposed area that the implant species may have to traverse.

In some examples, isolation implantation may be performed before patterning the p-GaN layer that covers the barrier layer of a heterojunction structure. In such arrangements, the photoresist is formed over the unpatterned p-GaN layer, which shields the underlying barrier layer from contacting the photoresist. However, because the photolithography stage for patterning an isolation implant photoresist may require a patterned feature on the wafer for facilitating alignment, lack of a patterned p-GaN layer may render the photoresist photolithography process challenging. To overcome this issue, a separate mask having alignment markers or fiducials may be required in order to facilitate pattern recognition and alignment with respect to forming a patterned photoresist. Accordingly, whereas the barrier layer may be protected against photoresist contamination, additional process complexity and manufacture cost may be incurred in such examples.

Examples of the present disclosure recognize the foregoing challenges and provide solutions for mitigating various issues associated with isolation implant process steps in a GaN process flow, for example barrier layer contamination, passivation layer damage, among others. In some arrangements, a dielectric layer is provided over an unpatterned p-GaN layer that covers the barrier layer. As described in more detail herein, at least a portion of the p-GaN layer remains over the barrier layer during subsequent isolation implant process steps such that undesirable contact between the barrier layer and the photoresist can be avoided. After forming the dielectric layer, the dielectric layer may be patterned using a p-GaN photomask process to form a dielectric cap over the p-GaN layer in a gate region of the GaN device. In the examples herein, the dielectric cap may have a sufficient vertical topography to facilitate alignment with subsequent photoresist mask(s). The dielectric cap is also operable as a hard mask for patterning the p-GaN layer in a subsequent stage after the isolation implant process steps. Because the dielectric cap may be used for pattern recognition and alignment for subsequent photolithography process steps, the need for a separate mask having alignment markers is obviated—e.g., to facilitate isolation implant photolithography. As the dielectric layer is removed from the isolation regions in forming the dielectric cap over the p-GaN layer, the isolation implant process may be carried out with a lower implant energy. Whereas the examples herein may provide various structures, materials and processes that may engender these and other beneficial effects, no particular result is a requirement unless explicitly recited in a particular claim.

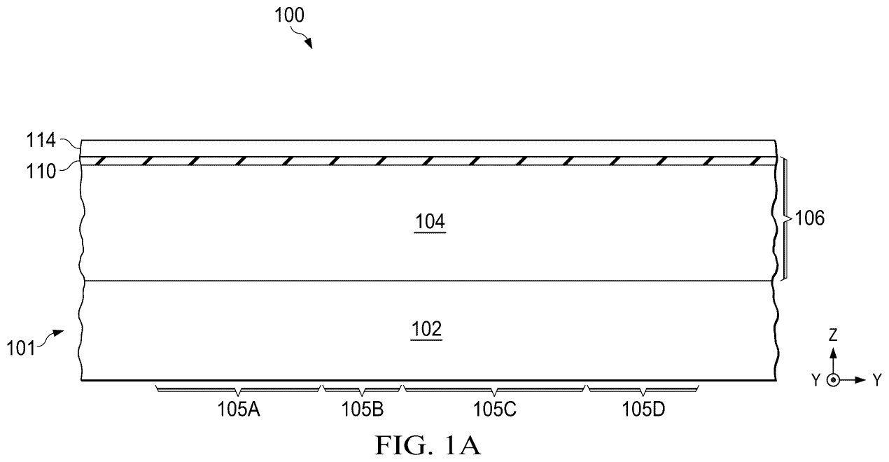

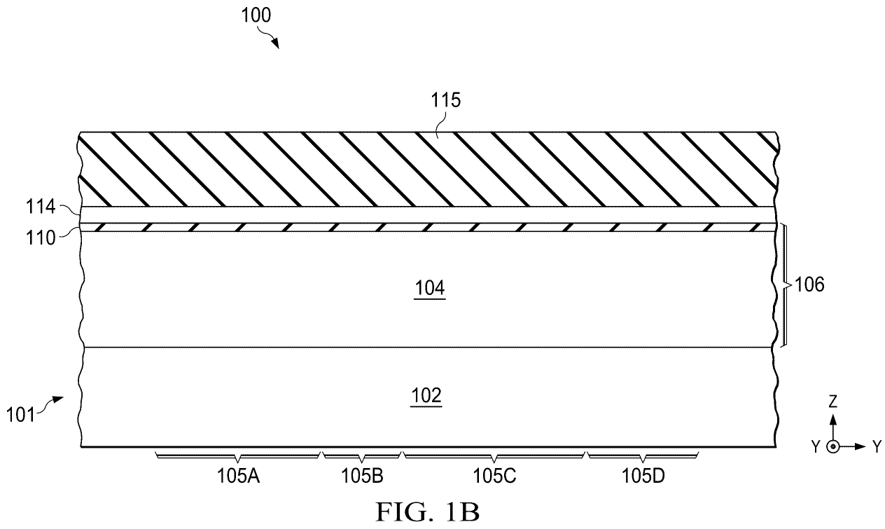

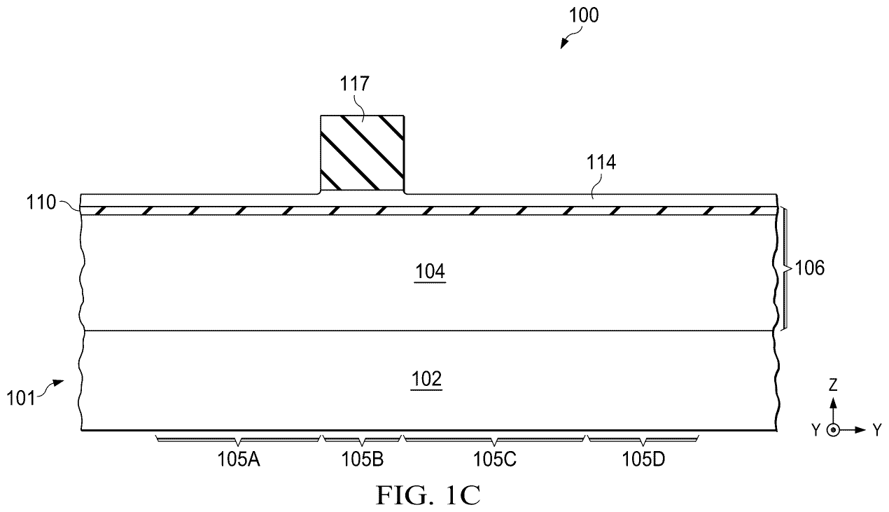

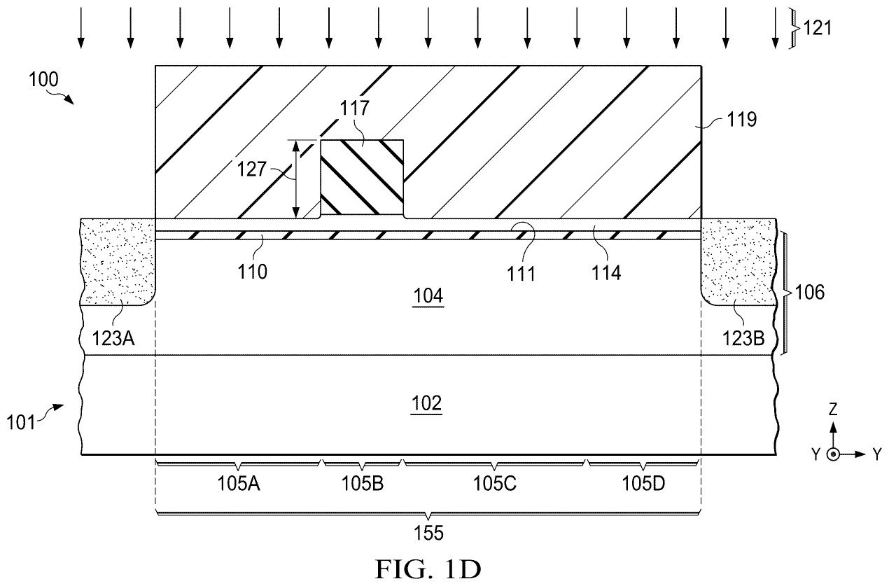

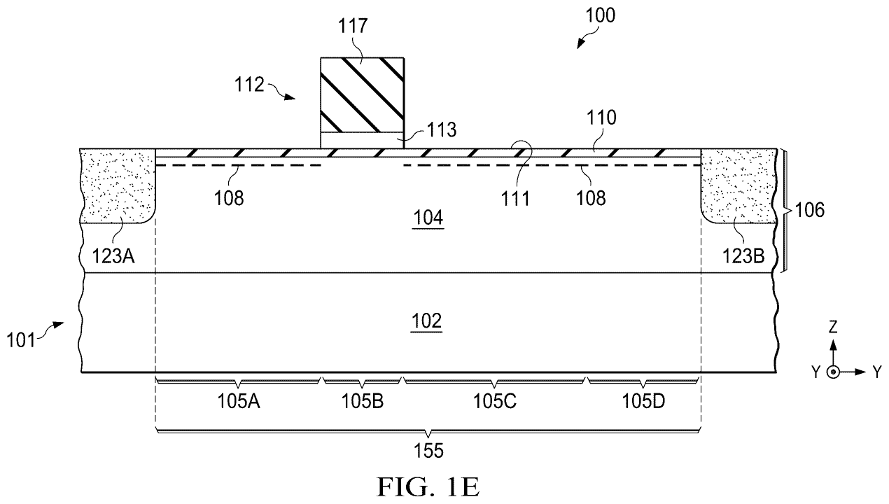

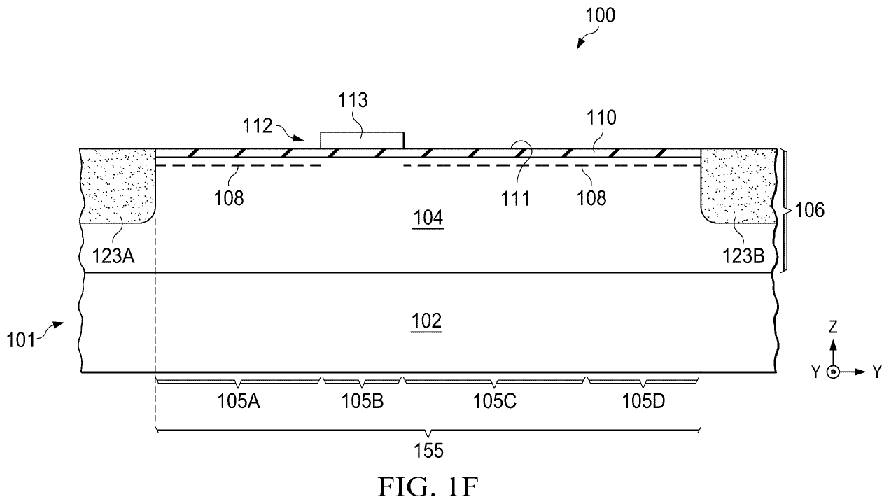

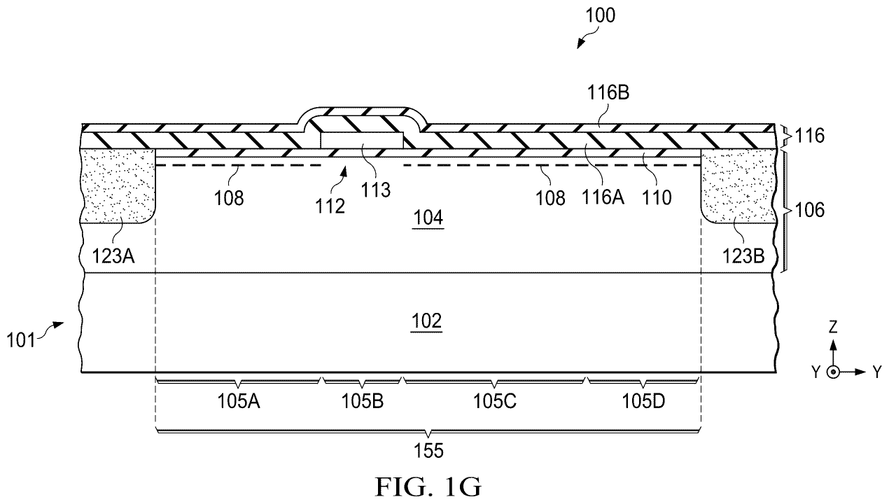

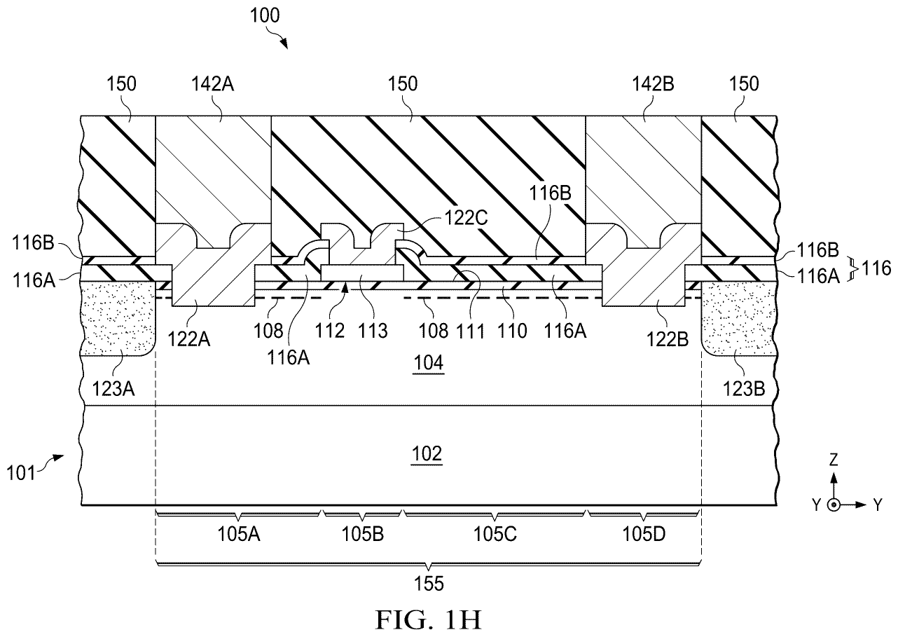

Referring to the drawings, FIGS. 1A-1H depict cross-sectional views of a semiconductor device 100 at various stages of a process flow. The semiconductor device 100 includes a GaN device 101 having an isolation region (which may be referred to as a device isolation region) according to an example of the present disclosure.

FIG. 1A depicts an intermediate stage of the semiconductor device 100 formed on a portion of a semiconductor substrate 102, which may be provided as a silicon wafer, a silicon-on-sapphire wafer, or a silicon carbide wafer, and/or as semiconductor substrates including cores configured for matching coefficient of thermal expansion (CTE), and/or the like. A buffer layer 104 comprising one or more layers of III-N semiconductor material is formed on the substrate 102. In some examples where the substrate 102 is implemented as a silicon wafer or a sapphire wafer, the buffer layer 104 may include a nucleation layer having a stoichiometry that includes aluminum to match a lattice constant of the substrate 102. In some examples, the buffer layer 104 may further include layers/sublayers of aluminum gallium nitride (AlGaN) with decreasing aluminum content, including an unintentionally doped (UID) GaN sublayer in some arrangements. For purposes of the examples herein, the various layers/sublayers of a buffer layer, e.g., the buffer layer 104, are not specifically shown in the Figures of the present disclosure.

Depending on implementation, the buffer layer 104 may have a thickness of about 1 micron (μm) to several microns, e.g., 3.5 μm to 7.0 μm, which may be formed by a suitable epitaxial process, e.g., a metal organic vapor phase epitaxy (MOVPE) process with several operations to form the various layers and/or sublayers. In some arrangements, an example buffer layer 104 may comprise a stack of multiple layers/sublayers of suitable materials and compositions (e.g., GaN, AlGaN, etc.) as noted above. In some arrangements, the layers/sublayers of the buffer layer 104 may have variable thicknesses depending on the technology and device application. In some arrangements, the buffer layer 104 may include AlGaN-based transition layers, epitaxial layers with strain-layer superlattice (SLS) structures, and the like.

The buffer layer 104 may be formed as part of an epitaxial III-N heterojunction structure, e.g., the heterojunction structure 106, over the substrate 102. The substrate 102 includes an isolation region that laterally surrounds a device area. For purposes of the present disclosure, the term “device area” may also refer to an area of the substrate 102 that is covered by a patterned photoresist during isolation implantation. The device area may also be referred to as an active area. The device area may include different regions of the GaN device 101 such as a source region 105A, a gate region 105B, a drain region 105D and a drain access region 105C between the gate region 105B and the drain region 105D. The source region 105A may be regarded as including a source access region (not specifically shown in the Figures), which may refer to a region between a source electrode (e.g., source electrode 122A as shown in FIG. 1H) and the gate region 105B similar to the drain access region 105C as will be set forth below.

For purposes of the present disclosure, an isolation region is a region or portion of the semiconductor substrate exposed in an isolation implant stage and implanted with suitable implant species such that the crystallinity of the heterojunction structure in the isolation region is damaged or destroyed. In some examples, the crystallinity of the heterojunction structure in the isolation region is sufficiently disturbed such that the constituent buffer and barrier layer materials in the exposed region may be in an amorphized or semi-amorphized state. According to the examples herein, the degree of amorphization or semi-amorphization of the buffer and barrier layers in the isolation region may be adequate to prevent the formation of a conductive channel, e.g., a 2DEG, in the isolation regions. Further, the implant species may cause various structural and/or morphological changes in the isolation regions as will be set forth further below. Conversely, an active area or a device area (or region) of the semiconductor substrate is not exposed to an isolation implant—e.g., covered by a photoresist disposed over the active or device area. Accordingly, the crystallinity of the heterojunction structure in the device area is preserved. In this manner, the capability of the heterojunction structure in the device area to support the formation of a conductive channel (e.g., 2DEG) is retained.

A channel layer may be provided as part of the buffer layer 104—e.g., a top portion of the buffer layer 104 proximate to a barrier layer 110. Whereas a channel layer may primarily include GaN material, there may be optional trace amounts of other group III elements, such as aluminum or indium, in some implementations. A barrier layer 110 comprising III-N semiconductor material and suitable thickness is formed over the buffer layer 104. In an example arrangement, the barrier layer 110 may have a thickness ranging from about 1 nanometer (nm) to about 60 nm, and may include aluminum and nitrogen. In some versions of this example, the barrier layer 110 may include gallium at a lower atomic percent than aluminum. In some versions, the barrier layer 110 may also include indium. In some examples, the barrier layer 110 includes an AlGaN layer.

The barrier layer 110 over the buffer layer 104 is operable as part of a heterojunction structure 106 for causing the formation of a 2DEG (e.g., 2 DEG 108 shown in FIG. 1E) proximate to an interface between the barrier layer 110 and the buffer layer 104. In some examples, the stoichiometry and thickness of the barrier layer 110 may be configured to provide a suitable free charge carrier density (e.g., 3×10¹² cm⁻² to 2×10¹³ cm⁻²) of the 2DEG for facilitating the device operation.

For purposes of effectuating EMODE functionality, a p-doped III-N layer 114, e.g., comprising one or more layers of III-N material, is formed over the barrier layer 110 as shown in FIG. 1A. In some examples, the p-doped III-N layer 114 may also be referred to as a p-III-N layer or a p-GaN layer. In versions of this example, the p-doped III-N layer 114 may comprise a GaN layer doped with magnesium (Mg) or other suitable p-type dopants. In some examples, the p-doped GaN layer 114 may include a p-dopant concentration of about 1×10¹⁷ atoms/cm³ to 1×10²¹ atoms/cm³ and may have a thickness of about 10 nm to 200 nm. In some additional and/or alternative arrangements, additional layers such as an AlGaN cap layer (e.g., devoid of p-doping; not shown in the Figures) may be provided over the p-GaN layer 114.

In subsequent process stages, the p-GaN layer 114 may be patterned to form a p-GaN gate as part of a gate stack including a gate electrode in the gate region 105B. In the examples herein, the p-GaN layer 114 is also operable, prior to gate formation, as a photoresist (PR) blocking layer to shield the barrier layer 110 from having a direct contact with a photoresist during the isolation implantation stage as will be set forth below. Furthermore, the p-GaN layer 114 may be patterned after the isolation implantation stage using a dielectric cap as a hard mask. In this manner, the barrier layer 110 avoids contact with the photoresist during isolation implantation. Accordingly, the barrier layer 110 is advantageously free of organic photoresist material that may give rise to barrier layer contamination in some process flows as previously noted.

FIG. 1B depicts a stage where a dielectric layer 115 is formed over the unpatterned p-GaN layer 114 for facilitating the formation of a dielectric cap. In some versions of this example, the dielectric layer 115 may comprise a SiN layer having a thickness of about 50 nm to about 200 nm. In an example implementation, the dielectric layer 115 may be formed by a high temperature LPCVD process, e.g., at temperatures ranging from about 700° C. to about 850° C., using suitable precursors such as dichlorosilane (DCS) and ammonia (NH₃). In some arrangements, the dielectric layer 115 may comprise different materials, e.g., silicon dioxide (SiO₂), silicon oxynitride (SiON), aluminum oxide (Al₂O₃), aluminum nitride (AlN) etc., and may be formed using other techniques such as ALD. In some arrangements, the dielectric layer 115 may be referred to as a first dielectric layer or a sacrificial dielectric layer in relation to other dielectric layers that may be formed at later stages during fabrication.

FIG. 1C depicts a stage after patterning the dielectric layer 115 using a mask (e.g., a p-GaN mask) and photolithography process in combination with an etch process (e.g., SiN etch process) to form a dielectric cap 117 over the p-GaN layer 114 in the gate region 105B. Depending on implementation, the dielectric layer 115 may be etched using a dry etch, a wet etch, or a combination, having desirable selectivity against the III-N semiconductor material. In an example process flow, the SiN etch may also remove a portion (e.g., a top portion) of the p-GaN layer 114, e.g., due to overetching, while removing the dielectric layer 115 outside the gate region 105B.

FIG. 1D depicts an isolation implantation stage using a photoresist 119 that is patterned by suitable photolithography steps configured to expose regions 123A, 123B. Although the regions 123A, 123B are shown as two separate regions in the cross-sectional view of FIG. 1D, the regions 123A, 123B laterally surround a device area 155 with respect to the GaN device 101. As depicted, the device area 155 surrounded by the regions 123A, 123B includes the source region 105A, the drain region 105D, the gate region 105B, and the drain access region 105C disposed between the gate region 105B and the drain region 105D. In one example, an isolation process step may include implanting the semiconductor device 100 with appropriate implant species, e.g., implant species 121. The implant species 121 may have sufficient energy to cause damage to the crystallinity of the heterojunction structure 106 in the regions 123A, 123B. The regions 123A, 123B may also be referred to as isolation regions 123A, 123B. In some arrangements, an isolation implant having an energy of between 100 kilo-electron volts (keV) and 300 keV with an implant dose of 1×10¹⁴ ions/cm² to 1×10¹⁶ ions/cm² may be implemented to achieve device isolation. In some implementations, the implant species may comprise argon, silicon, fluorine, nitrogen, etc. Other implant species and implant energies are within the scope of the examples herein.

According to the examples herein, the implant species 121 may cause randomization of distances between constituent atoms, e.g., Ga, N, and Al, of the barrier layer 110 and the buffer layer 104 in the regions 123A, 123B. In some arrangements, the distances between the constituent atoms corresponding to respective crystal lattice constants may be disturbed in a stochastic manner due to the perturbations caused by the bombarding implant species 121. Accordingly, the barrier layer material and the buffer layer material in the isolation regions 123A, 123B may comprise matter in a state of disorder, resulting in a lack of clear demarcation between the layer boundaries. As a result, interfaces between the barrier layer 110 and the buffer layer 104 in the isolation regions 123A, 123B may become indistinct, blurred, etc. due to the mixing of constituent atoms during the implant step. In some arrangements, such mixing of the constituent atoms of the buffer and barrier layer materials may give rise to undulating surfaces within the isolation regions 123A, 123B.

Further, the mixing of the constituent atoms of the buffer and barrier layer materials in the isolation regions 123A, 123B gives rise to amorphized or semi-amorphized material therein. In some arrangements, the amorphized or semi-amorphized material of the isolation regions 123A, 123B may include isolation implant species. In some arrangements, the amorphized or semi-amorphized material may result in increased resistance, as a result of prohibiting (or reducing) the formation of the 2DEG in the isolation regions 123A, 123B as previously noted. Accordingly, the isolation regions 123A, 123B surrounding the device area 155 of the GaN device 101 may be regarded to be exclusive of a 2DEG (or free charge carriers such as electrons and/or holes) according to the examples herein. For purposes of the present disclosure, the terms “amorphous” and “amorphized” may include states of matter that may be considered “semi-amorphous” or “semi-amorphized” without necessarily being limited to any specific degree of crystalline damage in the isolation regions 123A, 123B.

As illustrated in FIG. 1D, the barrier layer 110 in the device area 155 is protected by the overlying p-GaN layer 114 during the implantation stage, where the p-GaN layer 114 is operable as a blocking shield between the barrier layer 110 and the patterned photoresist 119. Accordingly, direct contact between the barrier layer 110 and the patterned photoresist 119 is avoided. In this manner, a contaminant-free surface 111 of the barrier layer 110 may be obtained that advantageously reduces or eliminates adverse consequences, such as electron trapping during device operation. Because the dielectric cap 117 having a sufficient vertical topography in reference to the remaining p-GaN layer 114, e.g., a step height 127 along the Z-axis, may be used for pattern recognition and alignment in forming the patterned photoresist 119, there is no need for a separate mask having alignment markers to facilitate isolation implant photolithography. In the examples herein, therefore, the patterned photoresist 119 may be aligned based on the dielectric cap 117 to define the isolation regions 123A, 123B.

After the isolation implantation stage, the patterned photoresist 119 may be removed by a removal process, e.g., a plasma process using oxygen radicals and ions, such as an ash process, followed by a suitable wet clean process. Thereafter, the p-GaN layer 114 may be patterned using the dielectric cap 117 as a hard mask in combination with a suitable p-GaN etch process to form a p-GaN gate 113 as illustrated in FIG. 1E. As previously noted, the p-GaN gate 113 may be formed as part of a gate stack 112 including a gate electrode (e.g., gate electrode 122C in FIG. 1H) to be subsequently formed. As a result of patterning the p-GaN layer 114 (e.g., removing portions of the p-GaN layer 114 outside the gate region 105B), the 2DEG 108 may be formed outside the gate region 105B as illustrated in FIG. 1E. Moreover, the 2DEG 108 remains reduced—e.g., absent in some cases, in the gate region 105B to effectuate the normally off mode.

In some versions of the examples herein, the p-GaN gate 113 may be asymmetrically disposed in the device area 155 relative to the source region 105A (where a source electrode or contact is to be formed) and the drain region 105D (where a drain electrode or contact is to be formed) although it is not a requirement. For example, there may be a greater lateral distance between the gate region 105B and the drain region 105D than a lateral distance between the gate region 105B and the source region 105A by virtue of an access region, e.g., drain access region 105C, disposed between the gate region 105B and the drain region 105D. In some additional and/or alternative arrangements, a source access region may also be provided between the source region 105A and the gate region 105B in a similar manner, as previously noted, while still having source/drain region asymmetry with respect to the gate region 105B.

FIG. 1F depicts a stage after removing the dielectric cap 117 using a suitable removal process. Where the dielectric cap 117 comprises SiN, an example removal process may be a SiN wet etch including a solution of 85% phosphoric acid (H₃PO₄) and 15% de-ionized water maintained at a high temperature, e.g., around 150° C. to 180° C. In another example, the dielectric cap 117 may be removed in a SiN wet etch process using diluted hydrogen fluoride (HF).

Following the of removal the dielectric cap 117, one or more dielectric layers 116 (individually identified as dielectric layers 116A, 116B) operable as passivation layers may be formed over the p-GaN gate 113 and the barrier layer 110 as shown in FIG. 1G. Because such passivation layers are formed after the isolation implantation stage of FIG. 1D, they are devoid of isolation implant species. The passivation layers 116 extend across the boundary between the device area 155 and the isolation regions 123A, 123B. At least a portion of the passivation layers 116 (e.g., passivation layer 116A) directly touches (e.g., in contact with) the barrier layer 110. In some versions of this example, the dielectric layers operable as passivation layers may be referred to as a second dielectric layer, a third dielectric layer, and so on, in reference to the first dielectric layer 115 configured to provide a dielectric cap, e.g., dielectric cap 117, as set forth above. In some examples, the surface passivation layers may comprise one or more LPCVD SiN layers having thicknesses of about 10 nm to about 100 nm. In an example implementation, the passivation layers may be configured to provide desirable electrical characteristics of the GaN device 101, e.g., dynamic on-state resistance (R_{DSON}), time-dependent dielectric breakdown (TDDB), etc. In some arrangements, the passivation layers may comprise different materials, e.g., SiO₂, SiON, Al₂O₃, AlN, etc., and may be formed using other techniques such as ALD. Additional details regarding the formation of dielectric layers using LPCVD processes that may be used as passivation layers in some examples may be found in U.S. Patent Application Publication No. 2023/0094094, which is incorporated by reference herein in its entirety for all purposes.

FIG. 1H depicts a more completely formed semiconductor device 100 including the GaN device 101, where representative passivation layers 116A, 116B are illustrated. As depicted, a first passivation layer 116A is directly disposed on the barrier layer 110 having the contaminant-free surface 111. A second passivation layer 116B is disposed over the first passivation layer 116A. In the example shown in FIG. 1H, both passivation layers 116A, 116B extend across the device area 155 and over the isolation regions 123A, 123B. As noted previously, the passivation layers 116A, 116B are exclusive of isolation implant species.

Further, the GaN device 101 includes source, drain and gate electrodes 122A-122C, respectively, formed in a gate first flow (e.g., where the source/drain electrodes are formed after forming the gate stack). Alternatively, the GaN device 101 may include source, drain and gate electrodes 122A-122C, respectively, formed in a gate last flow (e.g., where the source/drain electrodes are formed before forming the gate stack). The GaN device 101 also includes a source terminal 142A, a gate terminal (not shown in FIG. 1H) and a drain terminal 142B formed through an insulator 150 comprising, e.g., interlevel dielectric (ILD) and/or pre-metal dielectric (PMD) material, for facilitating electrical contact with source electrode 122A, drain electrode 122B and gate electrode 122C, respectively.

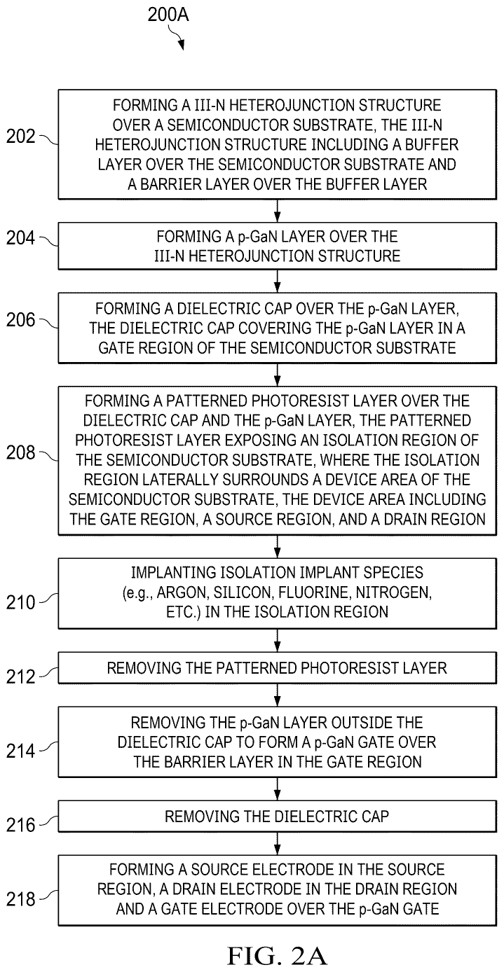

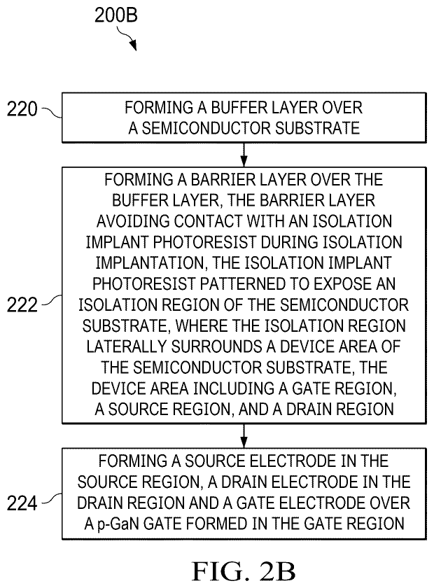

FIGS. 2A and 2B are flowcharts of methods of fabricating a semiconductor device according to some examples of the present disclosure. Method 200A shown in FIG. 2A may commence with forming a III-N heterojunction structure over a semiconductor substrate. The III-N heterojunction structure may include a buffer layer over the semiconductor substrate and a barrier layer over the buffer layer, as set forth at block 202. At least some aspects of block 202 may relate to the fabrication stage shown in FIG. 1A as described above. At block 204, a p-GaN layer may be formed over the III-N heterojunction structure, which may relate to some aspects set forth in FIG. 1A. At block 206, a dielectric cap may be formed over the p-GaN layer in a gate region of the semiconductor substrate, which may relate to some aspects of the fabrication stages shown in FIGS. 1B and 1C as described above.

At block 208, a patterned photoresist (PR) layer may be formed over the dielectric cap and the p-GaN layer. The patterned photoresist layer exposes an isolation region of the semiconductor substrate, where the isolation region laterally surrounds a device area of the semiconductor substrate. As previously set forth, the device area may include the gate region, a source region, and a drain region. In some arrangements, the processes set forth at block 208 may relate to aspects of FIG. 1D as described above. At block 210, one or more isolation implant species may be implanted into the isolation regions surrounding the device area. As previously set forth, the implant species may amorphize at least a portion of the III-N heterojunction material in the isolation regions. At least some aspects of block 210 may relate to the isolation implantation stage shown in FIG. 1D.

At block 212, the patterned photoresist layer may be removed, which may relate to some aspects associated with the fabrication stage shown in FIG. 1E as described above. Thereafter, the p-GaN layer may be patterned, e.g., using the dielectric cap as a hard mask, to remove the p-GaN layer outside the dielectric cap. Accordingly, a p-GaN gate is formed over the barrier layer in the gate region as set forth at block 214. At least some aspects of block 214 relate to the fabrication stage of FIG. 1E. After forming the p-GaN gate, the dielectric cap may be removed (block 216). Furthermore, one or more dielectric layers operable as surface passivation layers may be formed over the p-GaN gate and the barrier layer in some arrangements. As previously noted, the one or more surface passivation layers may be devoid of isolation implant species. Subsequently, a source electrode in the source region, a drain electrode in the drain region and a gate electrode over the p-GaN gate may be formed using a suitable process flow, e.g., a gate first flow or a gate last flow depending on implementation (block 218). At least some aspects of blocks 216 and 218 may relate to the fabrication stages shown in FIGS. 1F through 1H as described above.

Method 200B shown in FIG. 2B may commence with forming a buffer layer over a semiconductor substrate as set forth at block 220, which may relate to some aspects of the fabrication stage shown in FIG. 1A. At block 222, a barrier layer is formed over the buffer layer. According to the examples herein, a direct contact between the barrier layer and an isolation implant photoresist is avoided during isolation implantation. The isolation implant photoresist may be patterned to expose an isolation region of the semiconductor substrate, where the isolation region laterally surrounds a device area of the semiconductor substrate. As previously stated, the device area may include a gate region, a source region, and a drain region. At least some aspects of block 222 may relate to the fabrication stages shown in FIGS. 1A-1D. At block 224, a source electrode in the source region, a drain electrode in the drain region and a gate electrode over the p-GaN gate may be formed similar to the processes set forth at block 218 described above.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A method, comprising:
forming a III-N heterojunction structure over a semiconductor substrate, the III-N heterojunction structure including a buffer layer over the semiconductor substrate and a barrier layer over the buffer layer;
forming a p-GaN layer over the III-N heterojunction structure;
forming a dielectric cap over the p-GaN layer, the dielectric cap covering the p-GaN layer in a gate region of the semiconductor substrate;
forming a patterned photoresist layer over the dielectric cap and the p-GaN layer, the patterned photoresist layer exposing an isolation region of the semiconductor substrate, wherein the isolation region laterally surrounds a device area of the semiconductor substrate, the device area including the gate region, a source region, and a drain region;
implanting isolation implant species in the isolation region;
removing the patterned photoresist layer;
removing the p-GaN layer outside the dielectric cap to form a p-GaN gate over the barrier layer in the gate region;
removing the dielectric cap; and
forming a source electrode in the source region, a drain electrode in the drain region and a gate electrode over the p-GaN gate.

2. The method of claim 1, further comprising:
forming a dielectric layer over the p-GaN layer; and
patterning the dielectric layer to form the dielectric cap.

3. The method of claim 2, wherein the patterning of the dielectric layer includes removing a portion of the p-GaN layer.

4. The method of claim 1, wherein the dielectric cap comprises low-pressure chemical vapor deposition (LPCVD) silicon nitride (SiN).

5. The method of claim 1, wherein the dielectric cap has a thickness ranging from about 50 nanometers (nm) to about 200 nm.

6. The method of claim 1, wherein the patterned photoresist layer is aligned based on the dielectric cap.

7. The method of claim 1, wherein the isolation implant species comprises at least one of argon, silicon, fluorine, and nitrogen.

8. The method of claim 1, further comprising:
after removing the dielectric cap, forming one or more surface passivation layers over the barrier layer and the p-GaN gate.

9. The method of claim 8, wherein the one or more surface passivation layers are devoid of isolation implant species.

10. The method of claim 8, wherein the one or more surface passivation layers include at least one of a SiN layer, a SiO₂ layer, a SiON layer, an Al₂O₃ layer, an AlN layer or a combination thereof.

11. A semiconductor device, comprising:
a semiconductor substrate including an isolation region laterally surrounding a device area, the device area including a gate region, a source region, and a drain region;
a III-N heterojunction structure over the semiconductor substrate, the III-N heterojunction structure including a buffer layer over the semiconductor substrate and a barrier layer over the buffer layer;
a p-doped III-N gate over the barrier layer in the gate region; and
a passivation layer over the barrier layer and the p-doped III-N gate, the passivation layer extending across the device area and the isolation region, wherein the passivation layer is exclusive of isolation implant species.

12. The semiconductor device of claim 11, wherein the barrier layer extends over the device area and the isolation region, the barrier layer exclusive of photoresist contaminants.

13. The semiconductor device of claim 12, wherein the photoresist contaminants comprise carbon-based compounds.

14. The semiconductor device of claim 11, wherein the barrier layer is an AlGaN layer.

15. The semiconductor device of claim 11, wherein the passivation layer is directly on the barrier layer.

16. The semiconductor device of claim 11, wherein the passivation layer is at least one of a SiN layer, a SiO₂ layer, a SiON layer, an Al₂O₃ layer, an AlN layer or a combination thereof.

17. The semiconductor device of claim 11, wherein the isolation implant species comprises at least one of argon, silicon, fluorine, and nitrogen.

18. The semiconductor device of claim 11, wherein the isolation region comprises a portion of the III-N heterojunction structure containing isolation implant species.

19. The semiconductor device of claim 11, wherein the isolation region is devoid of a 2DEG channel.

20. The semiconductor device of claim 11, wherein the isolation region comprises an amorphized portion of the III-N heterojunction structure.
